(19) United States
(12) Patent Application Publication
(10) Pub. No.: US 2004/0112373 A1
(43) Pub. Date: Jun. 17, 2004

(54) Passive Solar Tracker for a Solar Concentrator

(75) Inventor: Derek Djeu, Tampa, FL (US)

Correspondence Address: Derek Djeu, 15817 Sanctuary Drive, Tampa, FL, 33647

(73) Assignee: Derek Djeu, Tampa, FL (US)

(21) Appl. No.: 10/707,321

(22) Filed: Dec. 4, 2003

Related U.S. Application Data
(60) Provisional application No. 60/432,797, filed on Dec. 9, 2002.

(51) Int. Cl. H01L 25/00

(52) U.S. Cl. 126/604; 136/246

(57) ABSTRACT

The efficient operation of a solar concentrator requires the radiation collector to be pointed directly at the sun. The present invention represents one approach to a passive solar tracking system capable of focusing solar radiation onto a small target at all times of the year. The device consists of a two-axis gimbal system with its orientation controlled by interconnected ballasts filled with a volatile fluid. Accurate focusing is realized by ensuring that each significant mass element is balanced by another element of equal mass equidistant from and diametrically opposite to it through the point of intersection of the two gimbal axes for all possible orientations of the system.

### CROSS REFERENCE TO RELATED APPLICATIONS

This application claims the benefit of U.S. Provisional Application No. 60/432,797 filed on Dec. 9, 2002.

### BACKGROUND OF INVENTION

Solar power concentrators such as reflective dishes, lenses, and solar traps need to focus the sun's light on a single point or small area and operate best when aimed directly at the sun. For this reason many types of tracking devices have been developed to follow the sun from east to west each day and adjust also for seasonal changes in the sun's trajectory.

While many systems utilize motorized tracking systems and similar mechanically powered control systems, this invention represents a very simple type of system requiring no external power input.

The invention adapts a prior device that is a simple solar collecting system requiring no external power input, disclosed in U.S. Pat. No. 2,999,943 granted Sep. 12, 1961 to C. W. Geer. In this device a pair of closed containers interconnected in fluid communication are mounted on opposite sides of a pivot axis. Each container is partially filled with a low boiling point fluid, and the rest is filled with its vapor.

Each container is partially shielded from the sun. The shielding means are positioned in manner so that the sun equally irradiates the containers only when the device is aimed directly at the sun in east-west tracking. When the device is not aimed directly at the sun, one container receives more radiation than the other, causing differential evaporation of the fluid and forcing fluid to the opposite container due to the resulting pressure difference. The weight of the excess fluid on one side causes tipping until the device is aimed toward the sun.

After the sun sets, the collector will remain facing the last position from which the sun caused transfer of liquid, and in the morning the whole apparatus must wait until the sun's rays are high enough above the shield on the eastern container to strike the western container. When this occurs, the western container will transfer liquid to the eastern one until the collector has tipped back into a position from which it can begin tracking.

Another invention, disclosed in U.S. Pat. No. 4,275,712 granted Jun. 30, 1981 to Stephen C. Baer, improved upon this by adding heat collecting surfaces which contribute to the transfer of liquid between canisters, specifically in the morning. With this modification, tracking can commence earlier in the morning.

The previous solar tracking systems outlined in U.S. Pat. No. 2,999,943 and the improvements outlined in U.S. Pat. No. 4,275,712 do not address the needs of a solar concentrating device, which requires two degrees of tracking motion. The previous systems are limited to one degree of rotational motion and thus can only track one degree of the sun's motion across the sky.

For the purposes of a solar concentrator, which focuses the light on a single point or small area, the system is required to track two degrees of the sun's translational motion in the plane parallel to the earth's surface.

The present invention extends the previous single axis solar tracking systems to two orthogonal axes to serve the requirements of a solar concentrating system. Insofar as I am aware, there exists no tracking device that tracks both the sun's East to West movement and the sun's North and South movement, using the principles set forth herein.

### SUMMARY OF INVENTION

An object of the present invention is to precisely track the sun's daily motion across the sky all days of the year and concentrate the light from the sun onto a single specific point or small area, utilizing no external power input.

Briefly, this and other objects of this disclosure are accomplished in their broadest sense by mounting a solar concentrating device, such as a lens or reflective dish, on a platform affixed to a two-axis gimbal system, on which a pair of closed containers interconnected in fluid communication are mounted on opposite sides of each gimbal pivot axis.

Similar in concept to the aforementioned Geer patent, the two axes of the gimbal remain rotationally stationary only as long as the sun equally irradiates the pairs of containers on opposite sides of each axis. When the sun's position shifts, the system will redirect its aim until the angle of incidence of the sun's light is perpendicular to the plane of the solar concentrator platform. This orientation with respect to the sun is essential to the proper function of solar concentrators, such as lenses or reflective dishes, which focus light on a specified spot.

When the sun rises in the morning, the system will automatically flip from its orientation from the previous afternoon to an orientation that faces the rising sun, using the same principle stated above.

The introduction of a secondary axis of rotation imposes the new condition that the balancing of the device about the secondary axis does not interfere with the balancing about the primary axis. In other words, the part of the device supported by the secondary axis should produce negligible net torque about the primary axis in any of its possible orientations. In the present invention this requirement is satisfied by providing a counter-weight for every significant mass element supported by the secondary axis at a diametrically opposite location through the point where the primary and secondary axes cross. The latter is also the point at which solar radiation is directed.

### BRIEF DESCRIPTION OF DRAWINGS

FIG. 1 is a perspective view of one embodiment of the present invention with a two-axis gimbal, a solar concentrator, the four containers with shields that block the sun from radiating on the containers at certain angles.

FIG. 2 is a schematic of a preferred embodiment of the gimbal and the canisters viewed along the main axis.

FIG. 3 is a cross-sectional view of a representative light collection and focusing system.

FIG. 4a is the first of a sequence of positions, with black arrows showing the sunlight's angle of incidence on the system. It is a perspective view of one embodiment of the present invention in an arbitrary starting orientation, showing the direction of rotational motion.

FIG. 4b is the second of a sequence of positions. It is a perspective view of one embodiment of the present invention in an orientation that is facing the direction of the sun.

### DETAILED DESCRIPTION

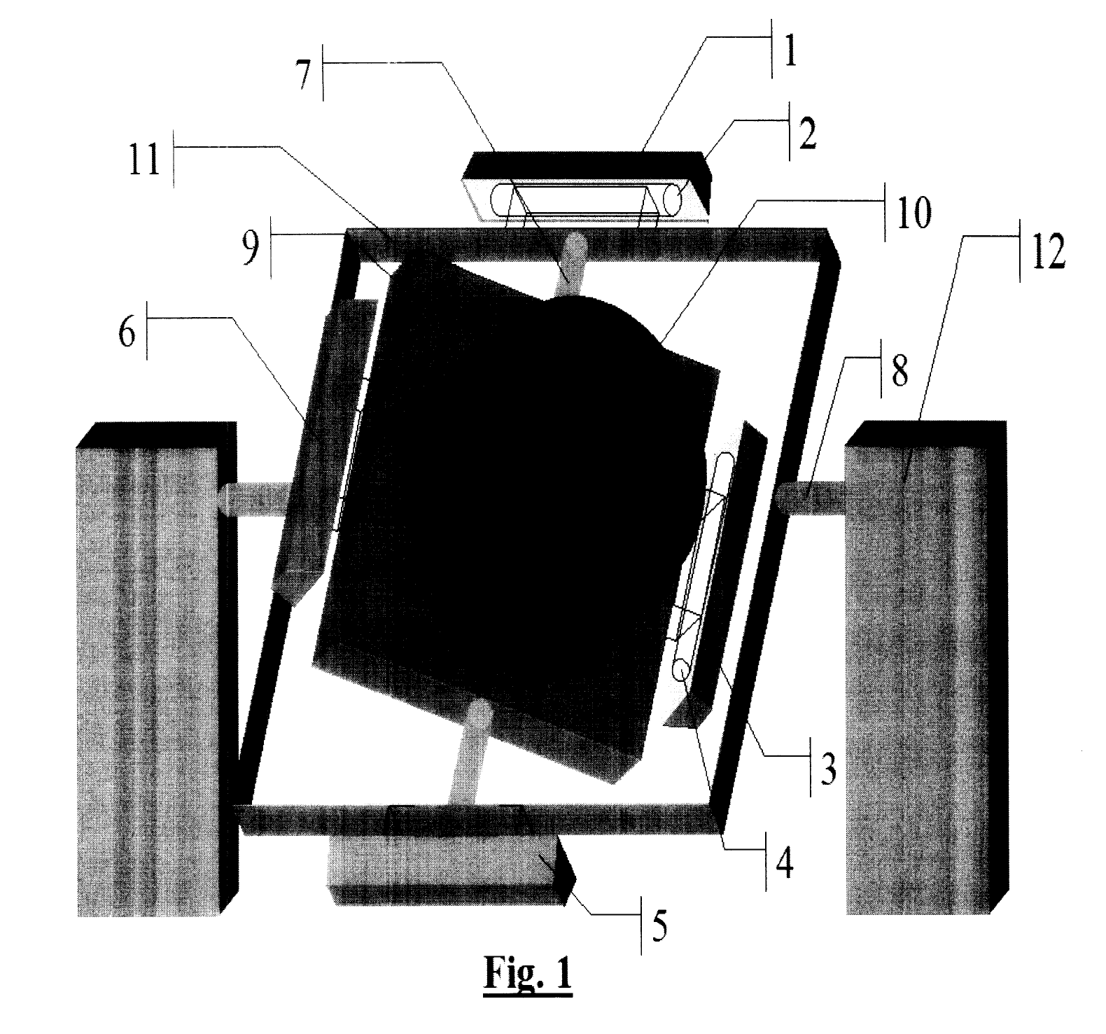

FIG. 1 is a perspective view taken with the gimbal in an arbitrary orientation. The base 12 is fixed to the ground and holds the main axis 8 of the gimbal. The main axis 8 rotates freely in the base 12 and is fixed to main gimbal frame 11. In the preferred embodiment, the main axis is aligned with north-south, so that the main gimbal frame can tilt toward east-west. Canister 2 is mounted on main gimbal frame 11 and is covered by shade 1. Another canister is mounted on the main gimbal frame 11 opposite canister 2 and is covered by shade 5. The canister under shade 5 and canister 2 are partially filled with a low-boiling point fluid and are in fluid communication.

Main gimbal frame 11 holds the secondary axis 7. Secondary axis 7 rotates within main gimbal frame 11 and is fixed to tracking platform 9.

Canister 4 is mounted on tracking platform 9 and is covered by shade 3.

Another canister is mounted on the tracking platform opposite canister 4 and is covered by shade 6. The canister under shade 6 and canister 4 are partially filled with a low-boiling point fluid and are in fluid communication.

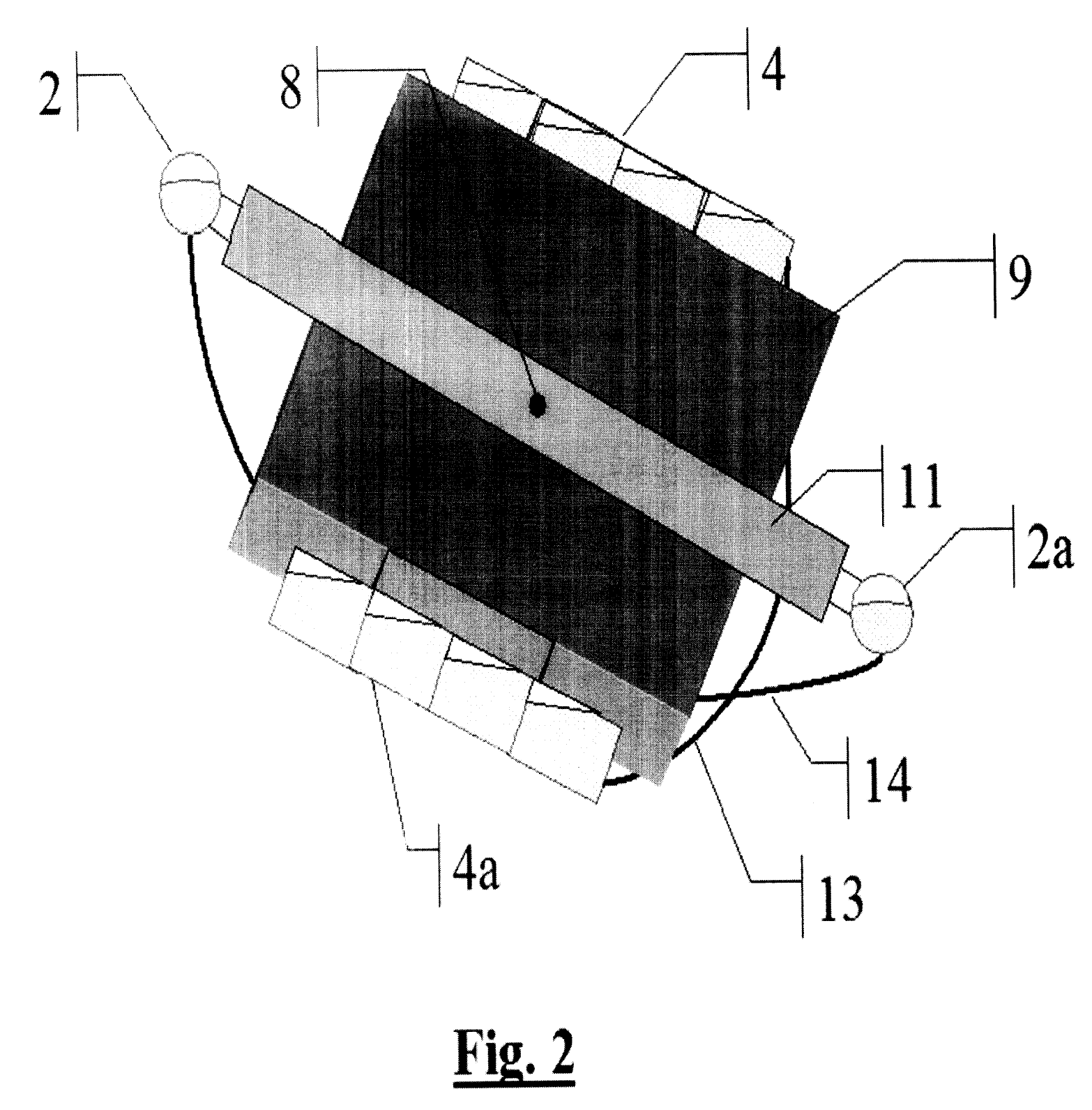

An end view along the primary axis of a preferred embodiment of the gimbal and canisters is shown schematically in FIG. 2. Canisters 4 and 4a are segmented, with each compartment connected fluidically to a corresponding one on the other side. (Only one such connecting tube, 13, is shown for simplicity.) The purpose of compartmentalization of canisters 4 and 4a is to minimize their effect on rotation of the main gimbal frame 11 about the main axis 8, caused by the fact that there must be a pocket of vapor at the top of each. This effect is not eliminated completely by compartmentalization. To further reduce it, in the preferred embodiment the vapor phase should occupy no more than a few percent of the total interior volumes of the canisters. While only 4 compartments are shown in each of canisters 4 and 4a, a larger number can be used for very high precision tracking. On the other hand, if a high degree of tracking precision is not needed in certain applications, canisters 4 and 4a can be built without any compartmentalization.

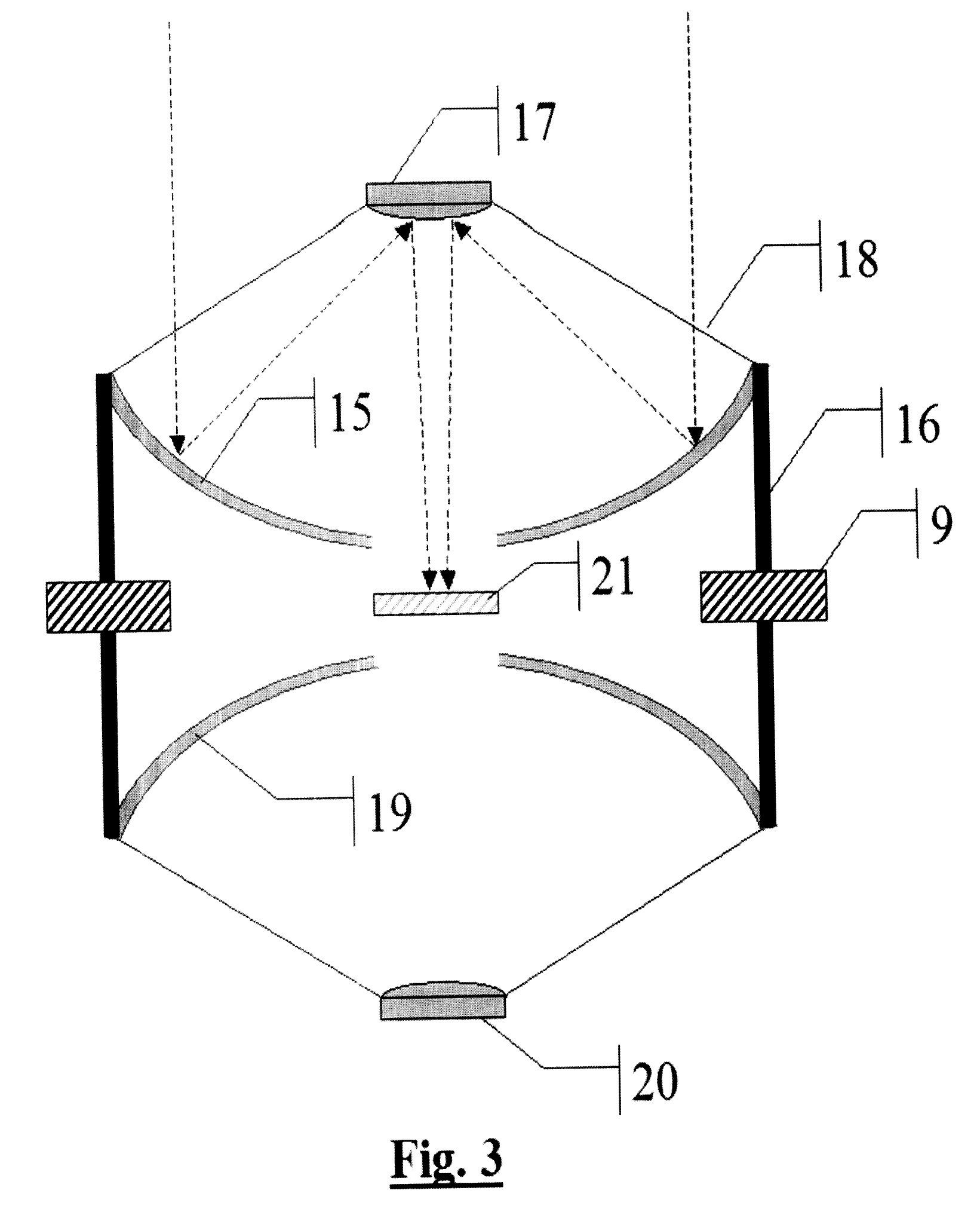

Again referring to FIG. 2, it can be seen that the liquid level in canister 2 is higher than that in canister 2a. This height difference can be quite substantial for a large tracking system. As a result, the vapor pressure in canister 2 must be lower than that in canister 2a for the orientation shown in FIG. 3 by the pressure head represented by the height difference. What this means is that the equilibrium orientation does not truly correspond to equal irradiation of canisters 2 and 2a. Instead, it corresponds to a situation where the temperature of canister 2a is slightly higher than that of canister 2. In the preferred embodiment, the volatile fluid has a vapor pressure that changes fast enough with temperature so that the temperature difference between canisters 2 and 2a at equilibrium does not exceed approximately 1 degree Celsius per meter separation. An example of such a fluid is dichlorodifluoromethane (CCl₂F₂).

FIG. 3 is a cross-sectional view of a representative light collection and focusing system. It consists of a parabolic mirror 15, which is affixed to the tracking platform 9 by means of struts 16, and mirror 17 which is attached to parabolic mirror 15 by struts 18. The parabolic mirror 15 has a hole at the apex to allow passage of light to strike target 21, which has its mid-plain coinciding with the mid-plain of tracking platform 9, indicated by the dotted line. The target is attached to tracking platform 9 by some means not shown in the figure so that the two rotate together. The dashed lines in the figure represent the paths of two rays of sunlight. In an optimized system, mirror 1 7 should be as close to parabolic mirror 15 as possible for compactness, and as small as possible to minimize obscuration of the incident sunlight. For these reasons, mirror 17 is shown as being convex. But other shapes, including planar and concave, can also be used. Depending on the application, the target may be placed before (as shown), in, or after the focus.

The target may be in the form of a light pipe such as an optical fiber or fiber bundle. In this case, the input end of the fiber or fiber bundle should be positioned at the focus for optimum coupling. Alternatively, the target may be a solar panel, in which case it should be in front of or behind the focus, so that overheating of the solar panel would not occur.

Again referring to FIG. 3, the parabolic mirror 15 and mirror 17 are balanced by similarly shaped counterweights respectively. As shown in FIG. 3, the counterweights 19 and 20 are symmetrically positioned with respect to mirrors 15 and 17 across the mid-plain of the tracking platform 9. Such an arrangement ensures that any torque produced by the collection and focusing optics about the main axis 8 is cancelled by the counterweights regardless of the orientation of the tracking platform 9. The counterweights may not be necessary if the optics and the supporting struts are sufficiently light and/or a high degree of tracking accuracy is not required.

The light collection and focusing system shown in FIG. 3 is merely illustrative. Many other architectures employing either reflective or transmissive optics, or combinations thereof, are also possible. Regardless of the particular system used, however, the counterweight condition set forth in the Summary or an approximation of it should be satisfied for precise tracking.

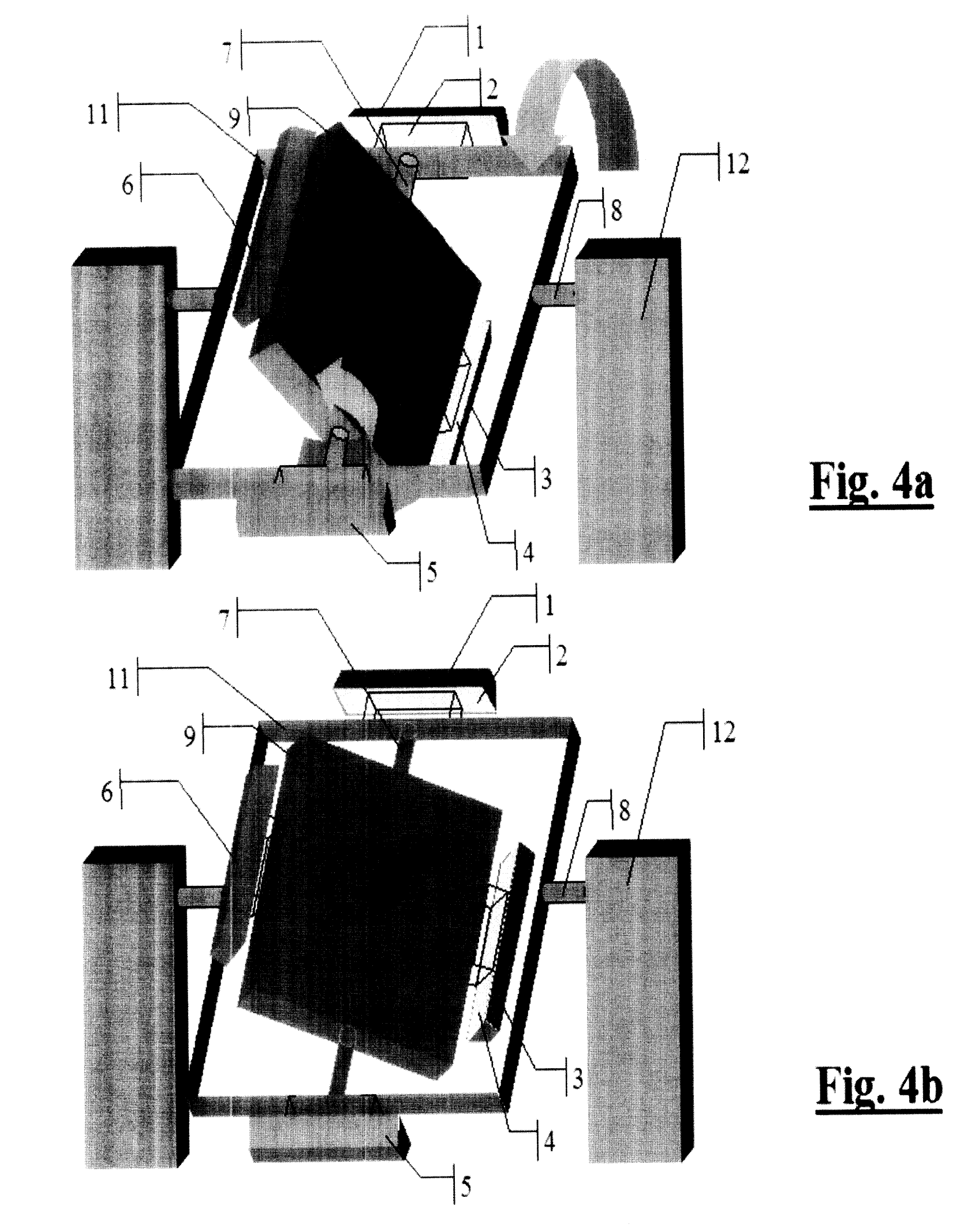

For the purpose of operational explanation, the solar concentrating device is not shown in FIG. 4a and FIG. 4b.

In FIG. 4a, the tracking device is in an arbitrary orientation with the sun radiating at an angle shown by black arrows. In this orientation, the sun's radiation strikes shield 6 and shield 5 and strikes canister 4 and canister 2.

Because canister 2 is being irradiated, its temperature will increase causing differential evaporation of the fluid and forcing fluid to the opposite container due to pressure differentials. The weight of the excess fluid on the colder side causes tipping around main axis 8.

Meanwhile, canister 4 is being irradiated forcing fluid to the opposite container. The weight of the excess fluid on the colder side causes tipping around the secondary axis 7.

Finally, in FIG. 4b, the tracking platform is directly facing the sun. In this orientation, all of the canisters are shielded from the sun, and thus both pairs of canisters are exactly balanced. The tracking system reaches a state of equilibrium under this condition.

Many other variations and modifications of the present invention will be apparent to those skilled in the art without departing from the spirit and scope of the invention. The above-described embodiments are, therefore, intended to be merely exemplary, and all such variations and modifications are intended to be included within the scope of the invention as defined in the appended claims.

1. A passive solar tracker and concentrating system comprising
a. a two-axis gimbal system in which a pair of containers partially filled with a volatile fluid are affixed to two opposing sides of the frame attached to each of the two orthogonal axes, each of said pair being in fluidic communication by means of a connecting tube, and each of said containers being shielded by a shade, so that the equilibrium orientation of the gimbal system corresponds to that where the plane defined by the inner gimbal frame faces the sun normally as a result of each of said pairs of containers being equally irradiated by the sun;
b. a light concentrating element attached to said two-axis gimbal system, which focuses the incident solar radiation; and
c. a target which intercepts said focused solar radiation.

2. A passive solar tracker and concentrating system according to claim 1 wherein said containers holding said volatile fluid are segmented and each of the sub-chambers is in fluidic communication with the corresponding one on the opposite side of the associated axis by means of a connecting tube.

3. A passive solar tracker and concentrating system according to claim 2 wherein each of said sub-chambers is substantially filled with said volatile fluid.

4. A passive solar tracker and concentrating system according to claim 2 wherein said volatile fluid increases its vapor pressure by more than approximately 10 kPa per degree Celsius increase in its temperature.

5. A passive solar tracker and concentrating system according to claim 1 wherein said light concentrating element is a lens.

6. A passive solar tracker and concentrating system according to claim 5 wherein each significant mass element is balanced by an equal mass element positioned at a diametrically opposite location through the point where the two axes of the gimbal intersect.

7. A passive solar tracker and concentrating system according to claim 1 wherein said light concentrating element consists of a reflective dish and a mirror positioned in front of the focus of the dish.

8. A passive solar tracker and concentrating system according to claim 7 wherein the reflective dish has a parabolic shape.

9. A passive solar tracker and concentrating system according to claim 7 wherein each significant mass element is balanced by an equal mass element positioned at a diametrically opposite location through the point where the two axes of the gimbal intersect.

10. A passive solar tracker and concentrating system according to claim 1 wherein said target is an optical fiber or fiber bundle.

11. A passive solar tracker and concentrating system according to claim 1 wherein said target is a solar panel.

12. A passive solar tracker and concentrating system according to claim 1 wherein said target is a thermally driven engine such as a Stirling engine.
